(19) United States
(12) Patent Application Publication
(10) Pub. No.: US 2025/0135721 A1
(43) Pub. Date: May 1, 2025

(54) STEREOLITHOGRAPHY THREE-DIMENSIONAL PRINTING OF FOAM MATERIALS CONTAINING HOLLOW MICROSPHERES

(71) Applicant: Impressio Inc., Denver, CO (US)

(72) Inventors: Amir H. Torbati, Westminster, CO (US); Rajib K. Shaha, Hillsboro, OR (US); Ross H. Volpe, San Diego, CA (US); Richard M. Wojcik, Denver, CO (US); Christopher M. Yakacki, Denver, CO (US); Risheng Zhou, Denver, CO (US)

(73) Assignee: Impressio Inc., Denver, CO (US)

(21) Appl. No.: 18/835,733

(22) PCT Filed: Feb. 1, 2023
(86) PCT No.: PCT/US2023/012108

§ 371 Date: Aug. 4, 2024

Related U.S. Application Data
(60) Provisional application No. 63/306,528, filed on Feb. 4, 2022.

(51) Int. Cl. B29C 64/314; B29C 64/124; B29K 105/00; B29K 105/16; B33Y 10/00; B33Y 40/10; B33Y 40/20; B33Y 70/10; B33Y 80/00

(52) U.S. Cl. CPC B29C 64/314; B29C 64/124; B29K 2105/0014; B29K 2105/0044; B29K 2105/165; B33Y 10/00; B33Y 40/10; B33Y 40/20; B33Y 70/10; B33Y 80/00

(57) ABSTRACT

In an embodiment, the present disclosure pertains to a method for forming a three-dimensional (3D) printing resin. In some embodiments, the method includes forming a mixture by combing a mesogen with a solvent and a stabilizer, heating the mixture, adding a spacer to the mixture, and adding a catalyst to the mixture. In some embodiments, the method further includes mixing a photoinitiator into the mixture. In some embodiments, the method further includes mixing a filler into the mixture. In some embodiments, the method further includes tailoring viscosity of the mixture. In some embodiments, the method further includes mixing a thermal initiator into the mixture. In an additional embodiment, the present disclosure pertains to methods of forming a material utilizing the 3D printing resin and a 3D foam device composed of a porous material printed into a form via the forming method.

### CROSS-REFERENCE TO RELATED APPLICATIONS

This patent application claims priority from, and incorporates by reference the entire disclosure of, U.S. Provisional Application 63/306,528 filed on Feb. 4, 2022.

### TECHNICAL FIELD

The present disclosure relates generally to three-dimensional printing and more particularly, but not by way of limitation, to stereo lithography three-dimensional printing of foam materials containing hollow microspheres.

### BACKGROUND

This section provides background information to facilitate a better understanding of the various aspects of the disclosure. It should be understood that the statements in this section of this document are to be read in this light, and not as admissions of prior art.

Currently, many methods exist to create conventional polymer foams. These methods can include, for example, gas foaming or blowing, phase separation methods, high internal phase emulsion methods, breath figure methods, or direct templating methods. Additionally, various methods can incorporate the utilization of expandable or expanded microspheres. However, these traditional porous polymer preparation methods lack design flexibility and customization. For example, molds are typically needed, or post-processing (e.g., machining) is necessary in order to create desired shapes. In addition, some of these methods require special preparation conditions, such as, for example, high temperature or high pressure. In view of the aforementioned, there is a need to develop methods to increase design flexibility and customization, minimize or reduce post-processing, and to create methods that allow for manufacturing under conditions that are easily maintained (e.g., ambient conditions).

### SUMMARY OF THE INVENTION

This summary is provided to introduce a selection of concepts that are further described below in the Detailed Description. This summary is not intended to identify key or essential features of the claimed subject matter, nor is it to be used as an aid in limiting the scope of the claimed subject matter.

In an embodiment, the present disclosure pertains to a method for forming a three-dimensional (3D) printing resin. In some embodiments, the method includes forming a mixture by combing a mesogen with a solvent and a stabilizer, heating the mixture to improve miscibility, adding a spacer to the mixture, and adding a catalyst to the mixture. In some embodiments, the method further includes mixing a photoinitiator into the mixture, heating the mixture and remixing the mixture until the photoinitiator is fully dissolved. In some embodiments, the method further includes mixing a filler into the mixture until the filler is evenly distributed throughout the resin and allowing the mixture to cool to room temperature. In some embodiments, the filler is microspheres. In some embodiments, the method further includes tailoring viscosity of the mixture. In some embodiments, the tailoring includes adding a second solvent to the mixture. In some embodiments, the method further includes mixing a thermal initiator into the mixture.

In another embodiment, the present disclosure pertains to a printing resin composed of a mixture formed via a method of the present disclosure for forming a three-dimensional (3D) printing resin.

In an additional embodiment, the present disclosure pertains to a method of forming (e.g., printing) a material. In some embodiments, the method includes pouring a three-dimensional (3D) printing resin formed via the methods of the present disclosure into a 3D printer tank and printing the material. In some embodiments, the printing utilizes ultraviolet (UV) light to initiate a reaction of constituents in the 3D printing resin. In some embodiments, the printing utilizes heat to initiate a reaction of constituents in the 3D printing resin.

In a further embodiment, the present disclosure pertains to a three-dimensional (3D) foam device composed of a porous material printed into a form via a printing method (e.g., forming a material) of the present disclosure.

### BRIEF DESCRIPTION OF THE DRAWINGS

A more complete understanding of the subject matter of the present disclosure may be obtained by reference to the following Detailed Description when taken in conjunction with the accompanying Drawings wherein:

FIG. 1 illustrates a schematic outlining stereo lithography (or digital light processing) printing utilizing microsphere (e.g., hollow microspheres) according to an aspect of the present disclosure.

FIG. 2 shows a comparison of silicone made EXPANCEL® and a liquid crystal elastomer (LCE) with EXPANCEL®.

FIG. 3 illustrates LCE material get softer as they warm to body temperature from room temperature.

FIG. 4 illustrates an example of the material response to cyclic loading, showing displacement and load over time.

FIG. 5 illustrates an example of a glassy-nematic, rubbery-nematic and isotropic LCE tested, measuring modulus and dissipation as a function of temperature.

FIG. 6 illustrates a direct comparison of dissipation in a traditional polymer network vs an LCE in which temperature is normalized to each polymer glass transition temperature.

FIG. 7 illustrates mesogen rotation.

FIG. 8 illustrates dynamic mechanical analysis (DMA) curves for 3D-printed resins of the present disclosure.

FIG. 9 illustrates tan ∂ comparison of an LCE to silicone.

FIG. 10 illustrates that LCEs show improved attenuation over a traditional viscoelastic foam.

FIG. 11 illustrates durometer measurements of silicone, a printed-solid LCE, and a printed-foam LCE.

### DETAILED DESCRIPTION

It is to be understood that the following disclosure provides many different embodiments, or examples, for implementing different features of various embodiments. Specific examples of components and arrangements are described below to simplify the disclosure. These are, of course, merely examples and are not intended to be limiting. The section headings used herein are for organizational purposes and are not to be construed as limiting the subject matter described.

Currently, various types of three-dimensional (3D) printed “foams” exist. In general, these “foams” can either utilize techniques in which a 3D printer prints an object and the material itself is porous, or a 3D printer can print an object where the structure is porous (i.e., a lattice) but the material itself is solid. The latter is generally referred to as a digital foam. In view of the desire to increase design flexibility and customization, the methods and compositions of the present disclosure generally pertain to methods in which the material itself is porous. Hierarchical designs typically use porous materials to print porous structures, and as such, the methods and compositions of the present disclosure seek to leverage 3D printing capabilities that utilize porous materials to print foams.

Various 3D printing methods are currently available. For example, nozzle-based printing and powder-based printing a frequently used. Nozzle-based printing generally extrudes an ink, resin, or filament through a nozzle, whereas powder-based printing generally fuses powder particles together with heat. These methods are commonly known as direct ink writing or fused filament fabrication and selective laser sintering or binder jetting, respectively. These methods, however, are inherently porous but can suffer from various setbacks, such as, lacking design flexibility and customization ability.

As such, the present disclosure generally relates to resin-based printing, also referred to as stereolithography (or digital light processing) to increase design flexibility and customization. Typically, resin-based printing utilizes a viscous liquid resin which is cured layer-by-layer using ultraviolet (UV) light. This technique generally forms solid components and was initially designed to avoid porosity of materials. As such, most resin-based printing methods are not used to print porous materials. However, the methods as disclosed herein, utilize a resin-based printing approach to form porous materials that achieve high ranges of porosity.

As set forth in further detail below, the present disclosure utilizes increased design flexibility and customization available with resin-based printing while still maintaining optimal porosity which is generally only available in nozzle- and powder-based printing processes. Additionally, as discussed in further detail below, the methods of the present disclosure can utilize microspheres to form a liquid crystal elastomer (LCE) viscous resin for use in stereo lithography printing. In general, high viscosity of the liquid crystal elastomer resin prevents spheres from settling to the bottom of the liquid crystal elastomer resin, or prevents spheres separating from the resin. Additionally, correct chemistry of the resin needs to be considered so that the resins do not dissolve shells of the microsphere (e.g., when using thermoplastic microspheres).

Such resins formed by the methods presented herein can be utilized such that materials can be formed which are highly customizable, require only minimal post-processing, can be manufactured at room temperature, and enable for easy control of porosity. Typically, the methods of the present disclosure, discussed in detail below, can include one or more of the generic steps of: (1) a resin reaction (e.g., a first state reaction that can include, for example, a Michael addition reaction); (2) preparation for; (3) mixing in microspheres; (4) tuning viscosity; (5) printing; and (6) post-processing.

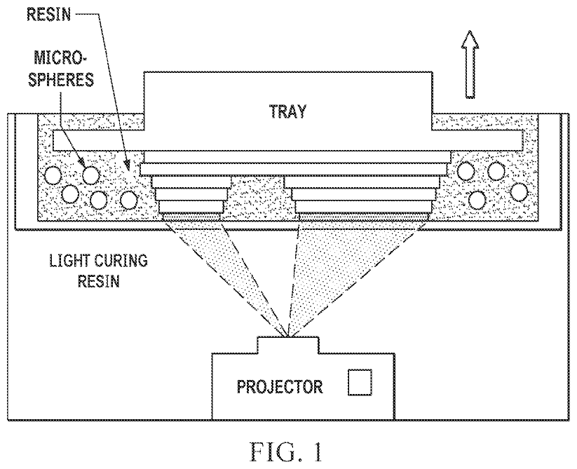

FIG. 1 illustrates a schematic outlining stereo lithography (or digital light processing) printing utilizing microsphere (e.g., hollow microspheres) according to an aspect of the present disclosure. While stereo lithography and digital light processing printing techniques were originally designed to avoid porosity of the material, utilizing the methods of the present disclosure can form compositions and materials with tailored porosity unlike similar processes utilizing other photocurable materials (e.g., photo-responsive ligand inorganic core; PLIC). For example, the methods as disclosed herein can achieve higher ranges of porosity, and unlike salt leeching techniques, can reach porosity levels lower than 60%.

One aspect of achieving these results, as will be discussed in further detail below, is considering the appropriate sizing of the microspheres for each application. For instance, the in diameters of the microspheres need to be under layer thickness of the printer, and for example, about 20 to 80 um microspheres are used with 100 um layer thickness.

In general, the methods of the present disclosure can form various materials and components in the form of, for example, printed foams. Utilizing the methods and compositions of the present, the printed foams can create a closed-cell liquid crystal elastomer. Furthermore, the printed foams can print as a solid part (e.g., a solid ear mold or a solid inner-ear mold) or as a macro-porous structure. Moreover, with 3D printing, the macro-porous can be designed to be an open-cell or closed-cell. Additionally, the printed foams can print components and materials exhibiting a combination of solid and porous properties. For example, an ear mold could be formed with a solid outer portion with a lattice inner portion.

While printed foams can be used to print numerous components, given that liquid crystal elastomers have improved sound attenuation properties, components for dampening sound can be greatly improved by the methods and compositions of the present disclosure. In general, porosity improves attenuation in materials.

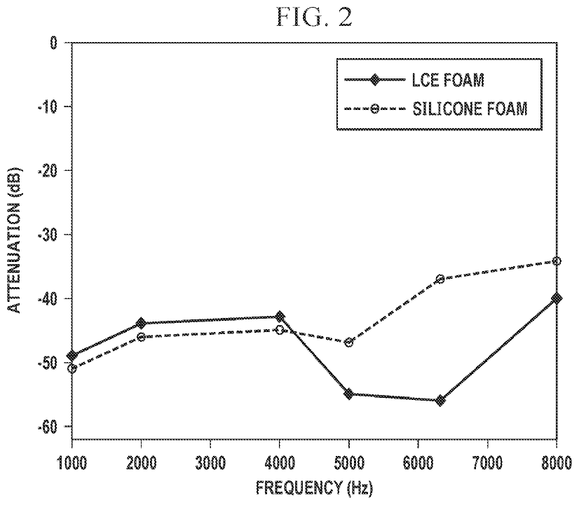

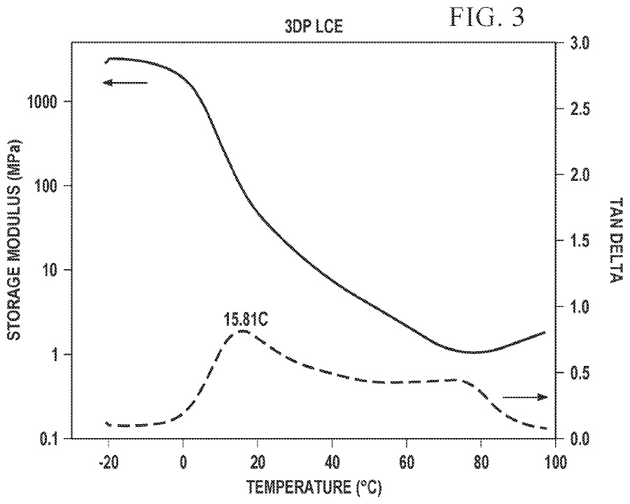

FIG. 2 shows a comparison of silicone made with EXPANCEL® and LCE with EXPANCEL®. The liquid crystal elastomer shows improved acoustic attenuation between 4000-8000 Hz (thicknesses of samples differ from previous figures, resulting in the magnitude of the values being different). Additionally, liquid crystal elastomer foams of the present disclosure get softer as they warm to body temperature going from approximately 20 MPa at room temperature to approximately 10 MPa at body temperature (FIG. 3). Silicone does not demonstrate the affect at the temperatures between room temperature and body temperature. This property can allow for increased comfort, for example a user of ear molds or devices using ear molds.

Furthermore, as the methods and compositions of the present disclosure utilize microspheres, other benefits can be achieved. The addition of microspheres can improve comfort of the device. For example, foams are compressible materials that can allow a wearing to compress the ear mold, insert it into the ear canal, and allow it to expand gently.

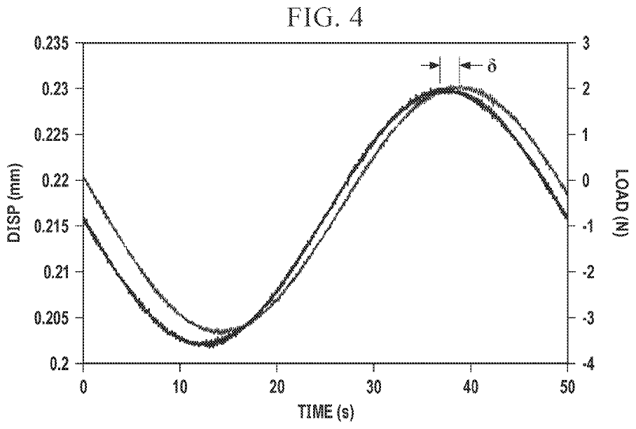

In general, storage modulus (E′) and tan ∂ are calculated via the following equations:

$${E}^{′} = \frac{σ}{ε} sin δ \\ {E}^{″} = \frac{σ}{ε} cos δ \\ tan δ = \frac{{E}^{″}}{{E}^{′}}$$

where δ is defined as the phase lag between two sine waves, a load (stress) and displacement (strain) wave (measured in radians). Perfectly elastic materials, such as metals, ceramics, and hard plastics are in phase and have ∂ and tan ∂ values ˜0. Mathematically, this is expressed when E″ (or loss modulus) is equal to 0, meaning all energy is stored elastically. FIG. 4 illustrates an example displacement and load over time.

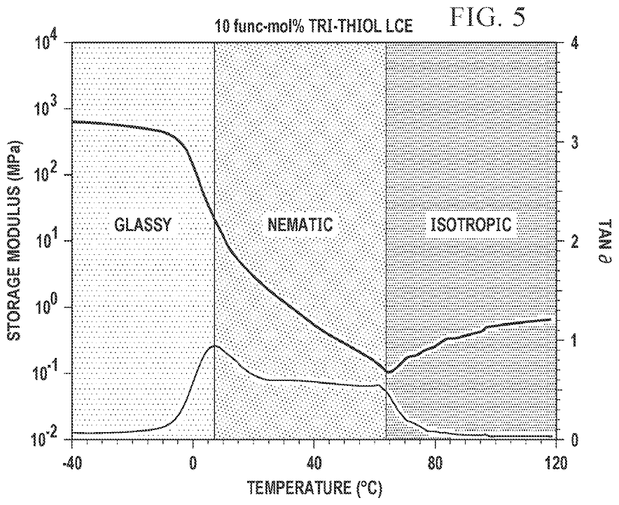

FIG. 5 illustrates an example of a nematic liquid crystal elastomer tested. The glassy region of the polymer behaves like a traditional polymer network. The liquid-crystalline (i.e., nematic) region shows an elevated tan ∂ (bottom of curve curve). The isotropic region shows the tan δ returns to a normal low value (˜0) and behaves like a traditional polymer network. It should be noted that there is a dip in the storage modulus at Tᵢ when it transitions from nematic to isotropic.

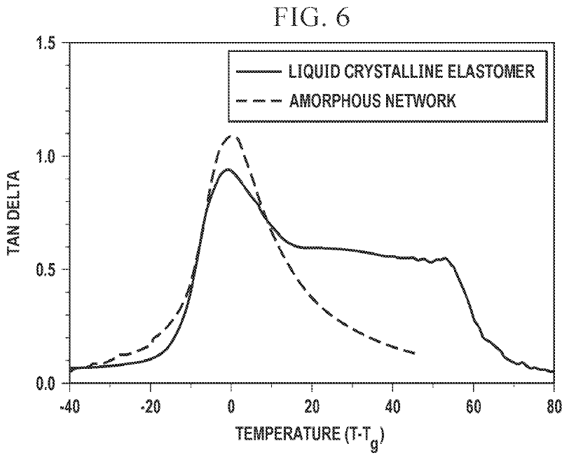

FIG. 6 illustrates a direct comparison of a traditional polymer network vs a liquid crystal elastomer (“Amorphous Network” is to be interpreted as a traditional elastomer). The polymers have similar crosslink density and structure, as the first half of the tan ∂ functions and peak of tan ∂ are similar. FIG. 6 shows the elevated tan ∂ when heated past the T_{g}. One distinguishing feature of liquid crystal elastomers to conventional elastomers is that the tan ∂ remains elevated above T_{g}.

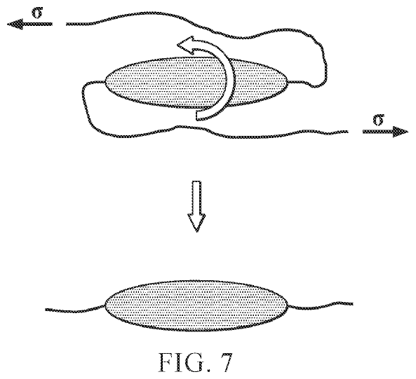

FIG. 7 illustrates mesogen rotation. Liquid crystals have long range order (like traditional crystals). However, unlike traditional crystals, the mesogens are not frozen in place and confined to on configuration. The mesogens can rotate the accommodate stress while still keeping order. This rotation in the system allows for enhanced energy dissipation above T_{g}.

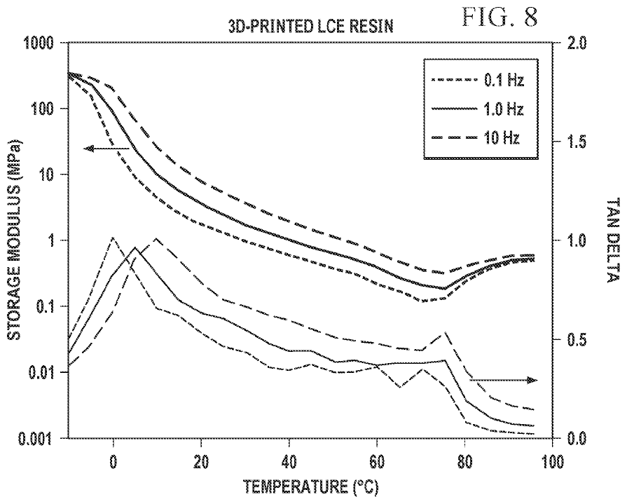

FIG. 8 illustrates dynamic mechanical analysis (DMA) curves for 3D-printed resins of the present disclosure. FIG. 8 shows glass transition temperature is around 0° C., meaning the polymer is considered elastomeric around body temperature. The tan ∂ remains elevated around body temperature. An elevated tan ∂ is preferred for vibration isolation and acoustic attenuation.

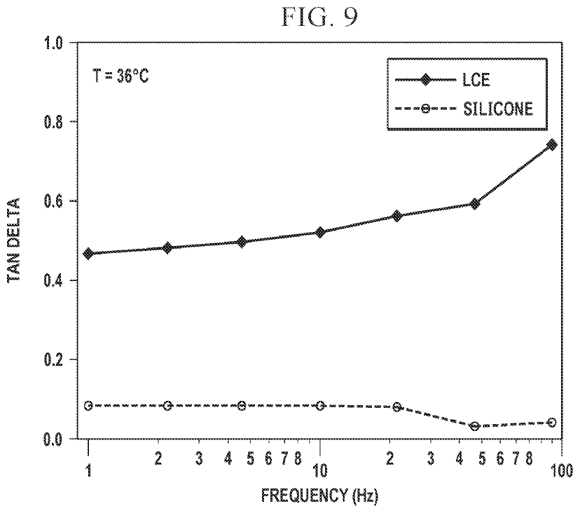

FIG. 9 illustrates tan ∂ comparison of a liquid crystal elastomer to silicone. Liquid crystal elastomers show a much higher tan ∂ compared to a traditional elastomer used in inner ear molds (silicone).

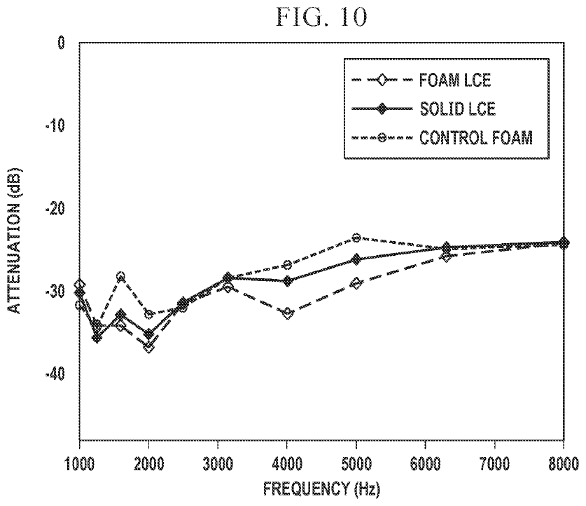

With respect to acoustic attenuation, FIG. 10 illustrates that liquid crystal elastomers show improved attenuation over a traditional viscoelastic foam. This is due to extended and broad tan ∂ behavior. Liquid crystal elastomer foams show improved attenuation over solid liquid crystal elastomers. This is due to more scattering/reflection of acoustic waves in the material.

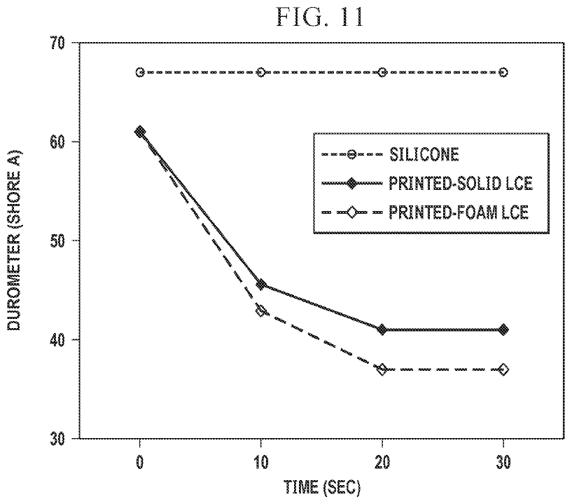

In general, LCE and LCE foams have better sound attenuation. An increased tan ∂ of a material will increase the sound attenuation performance of that material. Many materials tune their glass transition temperature (i.e., peak of tan ∂) to the operating temperature to help maximize their acoustic attenuation. However, materials at their glass transition temperature are not as soft/flexible as materials heated above their glass transition temperature. Silicones, which are extremely low modulus, are well above their glass transition temperature but have very low tan ∂ values. FIGS. 5, 6,7, and 9 show that LCEs are ideal acoustic attenuators because they can maintain a high tan ∂ value above their glass transition temperature, which is a unique combination of properties. Utilizing 3D printing foamed LCEs create very low durometer/stiffness materials (FIG. 11) with optimized acoustic attenuation.

FIG. 11 illustrates durometer measurements (i.e., a measurement of hardness) of silicone, a printed-solid liquid crystal elastomer, and a printed-foam liquid crystal elastomer. Traditional silicone inner ear materials do not show any visco-elastic effects. For example, when measuring their durometer, they remain constant. Liquid crystal elastomer materials demonstrate that the durometer can relax over time. This may improve comfort as the mold can relax within the ear canal. The Foam liquid crystal elastomer shows a lower durometer than solid liquid crystal elastomer.

In an embodiment, the present disclosure pertains to a method for forming a three-dimensional (3D) printing resin. In some embodiments, the method includes forming a mixture by combing a mesogen with a solvent and a stabilizer, heating the mixture to improve miscibility, adding a spacer to the mixture, and adding a catalyst to the mixture. In some embodiments, the heating can be conducted the heating is conducted between 8° and 100° C.

In some embodiments, the mesogen is a reactive mesogen. In some embodiments, the mesogen can include, without limitation, 2-methyl-1,4-phenylene bis(4-(3-(acryloyloxy) propoxy)benzoate), 4-[[[4-[(1-Oxo-2-propenyl)oxy]butoxy]carbonyl]oxy]benzoic acid 2-methyl-1,4-phenylene ester, 4-[4-[(1-oxo-2-propenyl)oxy]butoxy]-,2-methyl-1,4-phenylene ester, 2-methyl-1,4-phenylene bis(4-((6-(acryloyloxy) hexyl)oxy)benzoate), 4,4′-bis(acryloyl) biphenyl, 4-(6-(acryloyloxy) hexyloxy)phenyl 4-(6-(acryloyloxy) hexyloxy)benzoate, acrylic acid 6-[4′-(6-acryloyloxy-hexyloxy) biphenyl-4-yloxy]hexyl ester, 1,4:3,6-dianhydro-D-glucitol bis[4-[[4-[[[4-[(1-oxo-2-propenyl)oxy]butoxy]carbonyl]oxy]benzoyl]oxy]benzoate], 1,4-phenylene bis[4-[6-(acryloyloxy)hexyloxy]benzoate], 1,4-phenylene bis(4-((acryloyloxy) methoxy)benzoate), [4-(3-prop-2-enoyloxypropoxy)phenyl]4-(3-prop-2-enoyloxypropoxy)benzoate and combinations thereof. In some embodiments, the solvent can include, without limitation, toluene, dichloromethane, acetone, chloroform, tetrahydrofuran, benzene, hexane, and combinations thereof. In some embodiments, the stabilizer can include, without limitation, dibutylhydroxytoluene (butylated hydroxytoluene; BHT), 1,3,5-trimethyl-2,4,6-tris(3,5-di-tert-butyl-4-hydroxybenzyl)benzene, hydroquinone monomethyl ether, 2-(2-hydroxyphenyl)-2H-benzotriazoles, benzophenone, bisphenylene, and combinations thereof. In some embodiments, the spacer can include, without limitation, 2,2′-(ethylenedioxy)diethanethiol (EDDET), ethane-1,2-dithiol, 1,3-propanedithiol, 1,6-hexanedithiol, 1,9-nonanedithiol, 1,11-undecanedithiol, poly(ethylene glycol) dithiol, tetra(ethylene glycol) dithiol, hexa (ethylene glycol) dithiol, 1,4-benzenedimethanethiol, N-butylamine, ethylene glycol bis(3-mercaptopropionate), and combinations thereof. In some embodiments, the catalyst can include, without limitation, dipropylamine (DPA), hexylamine, triethylamine, tetramethyl-1,8-naphthalenediamine, 1,8-diazabicyclo[5.4.0]undec-7-ene, 1,5-diazabicyclo[4.3.0]non-5-ene, tripropylphosphine, dimethylphenylphosphine, methyldiphenylphosphine, pentamethyldiethylenetriamine, and combinations thereof.

In some embodiments, the catalyst initiates a chemical reaction between constituents in the mixture. In some embodiments, after adding the catalyst, the mixture can be sealed in a container and moved into an oven. In some embodiments, the container is heated for 8 or more hours at approximately 70° C. In some embodiments, the aforementioned steps mark the end of a first stage reaction.

In some embodiments, the method further includes mixing a photoinitiator into the mixture, heating the mixture, and remixing the mixture until the photoinitiator is fully dissolved.

In some embodiments, the photoinitiator can include, without limitation, phenylbis(2,4,6-trimethylbenzoyl) phosphine oxide (PPO), 2-hydroxy-2-methylpropiophenone, diphenyl(2,4,6-trimethylbenzoyl) phosphine oxide, bis(2,4,6-trimethylbenzoyl)-phenylphosphineoxide), 2,2-dimethoxy-2-phenylacetophenone, and combinations thereof. In some embodiments, the photoinitiator is added subsequent the aforementioned steps to avoid accidentally photo-polymerizing the printing resin prematurely. In some embodiments, the mixing of the photoinitiator can be done via vigorous shaking and/or stirring for several minutes. In some embodiments, the heating of the mixture with the photoinitiator can be conducted at approximately 70° C. In some embodiments, the remixing is conducted to insure complete dissolution of the photoinitiator.

In some embodiments, a thermal initiator can be added into the mixture. In some embodiments, the thermal initiator may be used to aid in the crosslinking of the resin. In some embodiments, the photoinitiators are used to form a shape through printing, and the thermal initiators are used to ensure complete crosslinking. In some embodiments, heat is utilized to cure each layer.

In some embodiments, thermal initiators can include, without limitation, peroxides, hydroperoxides, ketone peroxides, dialkyl peroxides, peroxyketals, peroxyesters, monoperoxy carbonates, diacyl peroxides, peroxy dicarbonates, tert-butyl peroxy-2-ethylhexanoate, n-butyl-4,4-di(tert-butylperoxy) valerate, 1,1-di(tert-butylperoxy)-3,3,5-trimethylcyclohexane, 1,1-bis(tert-amylperoxy)cyclohexane, 1,1-bis(tert-butylperoxy)cyclohexane, t-butyl peroxyneodecanoate, tert-butyl peroxybenzoate, and combinations thereof.

In some embodiments, a thermal initiator is utilized instead of a photoinitiator. In some embodiments, a thermal initiator is utilized in conjunction with a photoinitiator. In some embodiments, the resins of the present disclosure can be utilized to create thermally conductive composites.

In some embodiments, the method further includes mixing a filler into the mixture until the filler is evenly distributed throughout the resin and allowing the mixture to cool to room temperature. In some embodiments, the mixing can be conducted via vigorously shaking and/or stirring until the filler is evenly distributed in the mixture. In some embodiments, room temperature is between approximately 22 to 25° C.

In some embodiments, the methods of the present disclosure can include porous lattices. In some embodiments, the filler can include, without limitation, microspheres, EXPANCEL® 920 DE 80d30, EXPANCEL® 920 DE 40d30, EXPANCEL® 031 DU40, DUALITE® E135-025D, DUALITE® U015-135D, Kureha m330, Kureha m430, and combinations thereof. In some embodiments, the filler can be microspheres. In some embodiments, the microspheres are approximately 80 microns in diameter. In some embodiments, the microspheres are less than 80 microns in diameter. In some embodiments, the microspheres have a diameter as determined by a layer height while printing. For example, in some embodiments, if each layer is 100 microns, the diameters of the microspheres would be dictated by the layer height (e.g., 200 micron diameter height would be unacceptable). In some embodiments, the microspheres make up less than approximately 75% by volume (e.g., less than approximately 74% by volume). In some embodiments, the microspheres make up between approximately 5 to 30% by volume. In some embodiments, the microspheres can increase recoverability of a material formed with the 3D printing resin. In some embodiments, the microspheres are already expanded when put into the mixture. In some embodiments, the microspheres expand after the printing process is complete. In some embodiments, the microspheres are pre-expanded or unexpanded that expand when heated.

In some embodiments, the method further includes tailoring viscosity of the mixture via adding a second solvent to the mixture. In some embodiments, the tailored viscosity can be between approximately 2000 to 3000 cp. In some embodiments, when adding microspheres to the mixture, viscosity of the mixture is increased. In some embodiments, the second solvent can additionally disrupt liquid-crystal order thereby achieving better properties, such as, for example, dampening sound attenuation. In some embodiments, this further results in lowering viscosity of the mixture.

In some embodiments, the second solvent can include, without limitation, toluene, dichloromethane, acetone, chloroform, tetrahydrofuran, benzene, hexane, and combinations thereof.

In some embodiments, the method further mixing a thermal initiator into the mixture. In some embodiments, the thermal initiator can include, without limitation, peroxides, hydroperoxides, ketone peroxides, dialkyl peroxides, peroxyketals, peroxyesters, monoperoxy carbonates, diacyl peroxides, peroxy dicarbonates, tert-butyl peroxy-2-ethylhexanoate, n-butyl-4,4-di(tert-butylperoxy) valerate, 1,1-di(tert-butylperoxy)-3,3,5-trimethylcyclohexane, 1,1-bis(tert-amylperoxy)cyclohexane, 1,1-bis(tert-butylperoxy)cyclohexane, t-butyl peroxyneodecanoate, tert-butyl peroxybenzoate, and combinations thereof.

In another embodiment, the present disclosure pertains to a printing resin composed of a mixture formed via a method of the present disclosure for forming a three-dimensional (3D) printing resin.

In an additional embodiment, the present disclosure pertains to methods of forming a material (e.g., a printing method). In some embodiments, the method includes pouring a three-dimensional (3D) printing resin formed via the methods of the present disclosure into a 3D printer tank and printing the material. In some embodiments, the printing utilizes ultraviolet (UV) light to initiate a reaction of constituents in the 3D printing resin. In some embodiments, the reaction is a second stage reaction. In some embodiments, the 3D printing resin is UV cured layer-by-layer. In some embodiments, the printing is performed in ambient conditions.

In some embodiments, the UV light converts the 3D printing resin having a low molecular weight into a crosslinked liquid crystal elastomer. In some embodiments, the method further includes adding a color dye into the 3D printer tank prior to printing the material.

In some embodiments, the method further includes post-processing. In some embodiments, the post-processing can include, without limitation, washing the material in a solvent, post-curing the material in a UV oven, drying the material in a vacuum oven, mechanical buffing, dip coating (e.g., dip into a similar LCE resin or silicone resin to cure a thin glossy layer), and combinations thereof. In some embodiments, the post-processing ensures complete polymerization and/or eliminates “stickiness and/or tackiness” of the material (e.g., when utilizing post-curing in a UV oven). In some embodiments, post-processing can include activating a thermal initiator for post-curing. In some embodiments, the thermal initiator can be 2,2′-azobis(2-methylpropionitrile), tert-butyl peroxide, benzoyl peroxide, cumene hydroperoxide, and combinations thereof.

In some embodiments, the post-processing includes drying the material in a vacuum oven. In some embodiments, the drying can include, for example, heating the material for approximately 24 hours at 70° C. in the vacuum oven, then increasing temperature in the vacuum oven to 120° C. until the material is fully dried. In some embodiments, pressure in the vacuum oven is approximately 0.08 MPa. In some embodiments, a desiccant is placed in the vacuum oven to help absorb moisture. In some embodiments, removal of solvent, if the material is washed in a solvent, is performed in a gradual or slow manner. For example, in some embodiments, temperatures are gradually increased from a lower temperature to a higher temperature to prevent the material from cracking when removing the solvent.

In some embodiments, a design of the material is prepared and loading into the 3D printer. In some embodiments, the design accounts for shrinking of the material. For example, in some embodiments, after post-processing the materials can shrink by approximately 20%. As such, the design can take into account the approximate amount of shrinkage.

In some embodiments, the material is printed in a form that can include, without limitation, ear molds, sound isolation clips, acoustic panels and baffles, ear cushions and covers for headphones, vibration isolation pads, ear tips for earphones, packing bumpers, vibration isolators, shock isolators, base mounts, stud mounts, foot mounts, engine mounts, electronic equipment mounts, exhaust brackets, antivibration gloves, grips for rotary tools, grips for oscillating tools, grips for sporting equipment, and combinations thereof.

In a further embodiment, the present disclosure pertains to a three-dimensional (3D) foam device composed of a porous material printed into a form via a printing method (e.g., forming a material) as described in detail herein.

In some embodiments, the form includes at least one of a solid portion, a lattice portion, or a macro-porous portion. In some embodiments, the form includes a solid outer form and a lattice inner portion.

In some embodiments, the 3D foam device exhibits slow recovery time when deformed and released. In some embodiments, the 3D foam device exhibits improved rate of recovery. In some embodiments, the 3D foam device exhibits a high range of porosity. In some embodiments, the 3D foam device has a tailored porosity.

In some embodiments, the 3D foam device exhibits lower overall stiffness/durometer. In some embodiments, the lower overall stiffness/durometer increases comfort of the 3D foam device. In some embodiments, the 3D foam device exhibits improved acoustic attenuation. In some embodiments, the improved acoustic attenuation increases performance of the 3D foam device.

In some embodiments, the 3D foam device exhibits a hierarchical structure. In some embodiments, the 3D foam device gets softer when temperature of the 3D foam device goes from room temperature to body temperature. In some embodiments, the 3D foam device is composed of a closed-cell liquid crystal elastomer foam.

In some embodiments, the 3D foam device has a form that can include, without limitation, ear molds, sound isolation clips, acoustic panels and baffles, ear cushions and covers for headphones, vibration isolation pads, ear tips for earphones, packing bumpers, vibration isolators, shock isolators, base mounts, stud mounts, foot mounts, engine mounts, electronic equipment mounts, exhaust brackets, antivibration gloves, grips for rotary tools, grips for oscillating tools, grips for sporting equipment, and combinations thereof.

Although various embodiments of the present disclosure have been illustrated in the accompanying Drawings and described in the foregoing Detailed Description, it will be understood that the present disclosure is not limited to the embodiments disclosed herein, but is capable of numerous rearrangements, modifications, and substitutions without departing from the spirit of the disclosure as set forth herein.

The term “substantially” is defined as largely but not necessarily wholly what is specified, as understood by a person of ordinary skill in the art. In any disclosed embodiment, the terms “substantially”, “approximately”, “generally”, and “about” may be substituted with “within [a percentage] of” what is specified, where the percentage includes 0.1, 1, 5, and 10 percent.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure. The scope of the invention should be determined only by the language of the claims that follow. The term “comprising” within the claims is intended to mean “including at least” such that the recited listing of elements in a claim are an open group. The terms “a”, “an”, and other singular terms are intended to include the plural forms thereof unless specifically excluded.

1. A method for forming a three-dimensional (3D) printing resin, the method comprising:
forming a mixture, wherein the forming comprises combining a mesogen with a solvent and a stabilizer;
heating the mixture to improve miscibility;
adding a spacer to the mixture; and
adding a catalyst to the mixture.

2. The method of claim 1, wherein the mesogen is selected from the group consisting of 2-methyl-1,4-phenylene bis(4-(3-(acryloyloxy) propoxy)benzoate)), 4-[[[4-[(1-Oxo-2-propenyl)oxy]butoxy]carbonyl]oxy]benzoic acid 2-methyl-1,4-phenylene ester, 4-[4-[(1-oxo-2-propenyl)oxy]butoxy]-,2-methyl-1,4-phenylene ester, 2-methyl-1,4-phenylene bis(4-((6-(acryloyloxy) hexyl)oxy)benzoate), 4,4′-bis(acryloyl) biphenyl, 4-(6-(acryloyloxy) hexyloxy)phenyl 4-(6-(acryloyloxy) hexyloxy)benzoate, acrylic acid 6-[4′-(6-acryloyloxy-hexyloxy) biphenyl-4-yloxy]hexyl ester, 1,4:3,6-dianhydro-D-glucitol bis[4-[[4-[[4-[(1-oxo-2-propenyl)oxy]butoxy]carbonyl]oxy]benzoyl]oxy]benzoate], 1,4-phenylene bis[4-[6-(acryloyloxy) hexyloxy]benzoate], 1,4-phenylene bis(4-((acryloyloxy) methoxy)benzoate), [4-(3-prop-2-enoyloxypropoxy)phenyl]4-(3-prop-2-enoyloxypropoxy)benzoate, and combinations thereof.

3. The method of claim 1, wherein the solvent is selected from the group consisting of toluene, dichloromethane, acetone, chloroform, tetrahydrofuran, benzene, hexane, and combinations thereof.

4. The method of claim 1, wherein the stabilizer is selected from the group consisting of dibutylhydroxytoluene (butylated hydroxytoluene; BHT), 1,3,5-trimethyl-2,4,6-tris(3,5-di-tert-butyl-4-hydroxybenzyl)benzene, hydroquinone monomethyl ether, 2-(2-hydroxyphenyl)-2H-benzotriazoles, benzophenone, bisphenylene, and combinations thereof.

5. The method of claim 1, wherein the spacer is selected from the group consisting of 2,2′-(ethylenedioxy)diethanethiol (EDDET); ethane-1,2-dithiol, 1,3-propanedithiol, 1,6-hexanedithiol, 1,9-nonanedithiol, 1,11-undecanedithiol, poly(ethylene glycol) dithiol, tetra(ethylene glycol) dithiol, hexa (ethylene glycol) dithiol, 1,4-benzenedimethanethiol, N-butylamine, ethylene glycol bis(3-mercaptopropionate), and combinations thereof.

6. The method of claim 1, wherein the catalyst is selected from the group consisting of dipropylamine (DPA), hexylamine, triethylamine, tetramethyl-1,8-naphthalenediamine, 1,8-diazabicyclo[5.4.0]undec-7-ene, 1,5-diazabicyclo[4.3.0]non-5-ene, tripropylphosphine, dimethylphenylphosphine, methyldiphenylphosphine, pentamethyldiethylenetriamine, and combinations thereof.

7. The method of claim 1, further comprising:
mixing a photoinitiator into the mixture;
heating the mixture; and
remixing the mixture until the photoinitiator is fully dissolved.

8. The method of claim 7, wherein the photoinitiator is selected from the group consisting of phenylbis(2,4,6-trimethylbenzoyl) phosphine oxide (PPO), 2-hydroxy-2-methylpropiophenone, diphenyl(2,4,6-trimethylbenzoyl) phosphine oxide, bis(2,4,6-trimethylbenzoyl)-phenylphosphineoxide), 2,2-dimethoxy-2-phenylacetophenone, and combinations thereof.

9. The method of claim 1, further comprising:
mixing a filler into the mixture until the filler is evenly distributed throughout the resin; and
allowing the mixture to cool to room temperature.

10. The method of claim 9, wherein the filler is selected from the group consisting of microspheres, EXPANCEL® 920 DE 80d30, EXPANCEL® 920 DE 40d30, EXPANCEL® 031 DU40, DUALITE® E135-025D, DUALITER U015-135D, Kureha m330, Kureha m430, and combinations thereof.

11. The method of claim 7, further comprising tailoring viscosity of the mixture, wherein the tailoring comprises adding a second solvent to the mixture.

12. The method of claim 11, wherein the second solvent is selected from the group consisting of toluene, dichloromethane, acetone, chloroform, tetrahydrofuran, benzene, hexane, and combinations thereof.

13. The method of claim 1, further comprising mixing a thermal initiator into the mixture.

14. The method of claim 13, wherein the thermal initiator is selected from the group consisting of peroxides, hydroperoxides, ketone peroxides, dialkyl peroxides, peroxyketals, peroxyesters, monoperoxy carbonates, diacyl peroxides, peroxy dicarbonates, tert-butyl peroxy-2-ethylhexanoate, n-butyl-4,4-di(tert-butylperoxy) valerate, 1,1-di(tert-butylperoxy)-3,3,5-trimethylcyclohexane, 1,1-bis(tert-amylperoxy)cyclohexane, 1,1-bis(tert-butylperoxy)cyclohexane, t-butyl peroxyneodecanoate, tert-butyl peroxybenzoate, and combinations thereof.

15. (canceled)

16. A method of forming a material, the method comprising:
pouring a three-dimensional (3D) printing resin into a 3D printer tank; and
printing the material, wherein the printing utilized at least one of visible light, near infrared (IR) light, ultraviolet (UV) light, or heat to initiate a reaction of constituents in the 3D printing resin.

17. The method of claim 16, wherein the at least one of visible light, near IR light, or UV light converts the 3D printing resin having a low molecular weight into a crosslinked liquid crystal elastomer.

18. The method of claim 16, further comprising adding a color dye into the 3D printer tank prior to printing the material.

19. The method of claim 16, further comprising post-processing.

20. The method of claim 19, wherein the post-processing is selected from the group consisting of washing the material in a solvent, post-curing the material in a UV oven, drying the material in a vacuum oven, mechanical buffing, dip coating, and combinations thereof.

21. The method of claim 16, wherein the material is printed in a form selected from the group consisting of ear molds, sound isolation clips, acoustic panels and baffles, ear cushions and covers for headphones, vibration isolation pads, ear tips for earphones, packing bumpers, vibration isolators, shock isolators, base mounts, stud mounts, foot mounts, engine mounts, electronic equipment mounts, exhaust brackets, antivibration gloves, grips for rotary tools, grips for oscillating tools, grips for sporting equipment, and combinations thereof.

22. A three-dimensional (3D) foam device comprising a porous material printed into a form via a printing method according to claim 16.

23. The 3D foam device of claim 22, wherein the form comprises at least one of a solid portion, a lattice portion, or a macro-porous portion.

24. The 3D foam device of claim 22, wherein the form comprises a solid outer form and a lattice inner portion.

25-33. (canceled)

34. The 3D foam device of claim 22, wherein the 3D foam device has a form selected from the group consisting of ear molds, sound isolation clips, acoustic panels and baffles, ear cushions and covers for headphones, vibration isolation pads, ear tips for earphones, packing bumpers, vibration isolators, shock isolators, base mounts, stud mounts, foot mounts, engine mounts, electronic equipment mounts, exhaust brackets, antivibration gloves, grips for rotary tools, grips for oscillating tools, grips for sporting equipment, and combinations thereof.
